(19) United States
(12) Patent Application Publication
(10) Pub. No.: US 2015/0340997 A1
(43) Pub. Date: Nov. 26, 2015

(54) CASCODE AMPLIFIER

(71) Applicants: Katsuya KATO, Tokyo (JP); Miyo MIYASHITA, Tokyo (JP); Toshihide OKA, Tokyo (JP); Kenichi HORIGUCHI, Tokyo (JP); Kazutomi MORI, Tokyo (JP); Kenji MUKAI, Tokyo (JP); Takanobu FUJIWARA, Tokyo (JP)

(72) Inventors: Katsuya KATO, Tokyo (JP); Miyo MIYASHITA, Tokyo (JP); Toshihide OKA, Tokyo (JP); Kenichi HORIGUCHI, Tokyo (JP); Kazutomi MORI, Tokyo (JP); Kenji MUKAI, Tokyo (JP); Takanobu FUJIWARA, Tokyo (JP)

(73) Assignee: MITSUBISHI ELECTRIC CORPORATION, Tokyo (JP)

(21) Appl. No.: 14/436,633

(22) PCT Filed: Nov. 9, 2012
(86) PCT No.: PCT/JP2012/079112

§ 371 Date: Apr. 17, 2015

(51) Int. Cl. H03F 1/22; H03F 3/193; H03F 3/21

(52) U.S. Cl. CPC H03F 1/223; H03F 3/21; H03F 3/193; H03F 2200/222; H03F 2200/315; H03F 2200/387; H03F 2200/451; H03F 2200/75

(57) ABSTRACT

A plurality of source-grounded transistors (3) are connected in parallel with each other, and a plurality of gate-grounded transistors (4) are connected in parallel with each other. Sources (4s) of the plurality of gate-grounded transistors (4) are connected to drains (3d) of the plurality of source-grounded transistors (3) respectively. Ground pads (5) are connected to sources (3s) of the plurality of source-grounded transistors (3). A plurality of grounding capacitances (6) are connected between gates (4g) of the plurality of gate-grounded transistors (4) and the ground pads (5). The plurality of source-grounded transistors (3) and the plurality of grounding capacitances (6) are alternately arranged between the ground pads (5) and the plurality of gate-grounded transistors (4).

### TECHNICAL FIELD

The present invention relates to a cascode amplifier mainly used for a mobile communication device such as a mobile phone.

### BACKGROUND ART

Development of cascode amplifiers using a CMOS process is currently being actively carried out as means for achieving low cost in power amplifiers for mobile phones based on CDMA or the like.

FIG. 6 is a circuit diagram illustrating a basic configuration of a cascode amplifier. The cascode amplifier is shown enclosed by a dotted line frame and the rest thereof are circuit elements necessary to constitute a power amplifier. Transistors Tr1 and Tr2 are n-channel MOS transistors and are cascode-connected. An amplifier using cascode-connected transistors is called a cascode amplifier.

A gate of the transistor Tr1 is connected to an RF input signal terminal IN via an input matching circuit and also connected to a gate bias terminal Vg1. A source of the transistor Tr1 is grounded. That is, the transistor Tr1 is a source-grounded transistor.

A gate of the transistor Tr2 is grounded via a capacitance C1 and also connected to a gate bias terminal Vg2. That is, the transistor Tr2 is a gate-grounded transistor. A source of the transistor Tr2 is connected to a drain of the transistor Tr1. A drain of the transistor Tr2 is connected to a drain power supply terminal Vd of the cascode amplifier via a line L1 and also connected to an RF output signal terminal OUT via an output matching circuit. The line L1 has a specific electrical length and acts as an inductor.

For conventional cascode amplifiers, a compound semiconductor such as GaAs having an excellent gain and efficiency is used. In recent years, in order to respond to increases in the amount of communication or the like in the mobile communication field, prime importance is placed on multimode multiband techniques compatible with a plurality of modulation schemes and a plurality of frequency bands. Furthermore, for mobile terminals, it is important to realize multimode multiband techniques in small sizes and at low cost. For this reason, cascode amplifiers using silicon devices are excellent in terms of integration and cost becoming a focus of attention for use in mobile terminals.

In a cascode amplifier using a compound semiconductor, a source of a source-grounded transistor is grounded using a via hole (e.g., see Non-Patent Literature 1). The via hole has small inductance, deterioration of device characteristics is small, and moreover there is no large constraint on the position of the via hole, and therefore a free layout is possible. In the case of a silicon device, however, via holes cannot generally be used, and so ground pads are provided on a silicon substrate and connected to an external ground via a wire.

### CITATION LIST

### Non-Patent Literature

Non-Patent Literature 1: Proceedings of the Electronics Society Conference of IEICE (Institute of Electronics, Information and Communication Engineers) 2011, C-2-22, by Takagi, Takayama, Ishikawa and Honjo

### SUMMARY OF INVENTION

### Technical Problem

Since a source of a source-grounded transistor is preferably fully grounded, a ground pad connected to the source is placed near the edge of a silicon substrate to reduce a wire inductance. Furthermore, it is preferable to increase the number of ground pads to reduce a combined inductance. However, an increase in the number of ground pads may cause an increase in the chip size.

Moreover, when there are many ground pads and transistors are large-sized, distances from gates of gate-grounded transistors to a grounding capacitance become non-uniform depending on positions of the gate transistors. For this reason, there is a problem that wiring resistance and inductance components from the gates to the grounding capacitance may cause unbalanced operation.

Furthermore, when parasitic resistance of wires from the gate-grounded transistors to the grounding capacitance is large, high-frequency grounding of the gates becomes insufficient, which may result in a problem of causing deterioration of the gain, output and efficiency of the cascode amplifier.

The present invention has been made to solve the above-described problems, and an object thereof is to provide a cascade amplifier capable of reducing the chip size, preventing unbalanced operation, and improving the gain, output and efficiency.

### Means for Solving the Problems

A cascode amplifier according to the present invention includes: a plurality of source-grounded transistors connected in parallel with each other; a plurality of gate-grounded transistors connected in parallel with each other and having sources connected to drains of the plurality of source-grounded transistors respectively; a ground pad connected to sources of the plurality of source-grounded transistors; and a plurality of grounding capacitances connected between gates of the plurality of gate-grounded transistors and the ground pad, wherein the plurality of source-grounded transistors and the plurality of grounding capacitances are alternately arranged between the ground pad and the plurality of gate-grounded transistors.

### Advantageous Effects of Invention

The present invention makes it possible to reduce the chip size, prevent unbalanced operation, and improve the gain, output and efficiency.

### BRIEF DESCRIPTION OF THE DRAWINGS

FIG. 1 is a top view illustrating a cascode amplifier according to Embodiment 1 of the present invention.

FIG. 2 is a partially enlarged top view of FIG. 1.

FIG. 3 is an enlarged top view illustrating a cascode amplifier according to a comparative example.

FIG. 4 is an enlarged top view illustrating a cascode amplifier according to Embodiment 2 of the present invention.

FIG. 5 is an enlarged top view illustrating a cascode amplifier according to Embodiment 3 of the present invention. FIG. 6 is a circuit diagram illustrating a basic configuration of a cascode amplifier.

### DESCRIPTION OF EMBODIMENTS

A cascode amplifier according to the embodiments of the present invention will be described with reference to the drawings. The same components will be denoted by the same symbols, and the repeated description thereof may be omitted.

### Embodiment 1

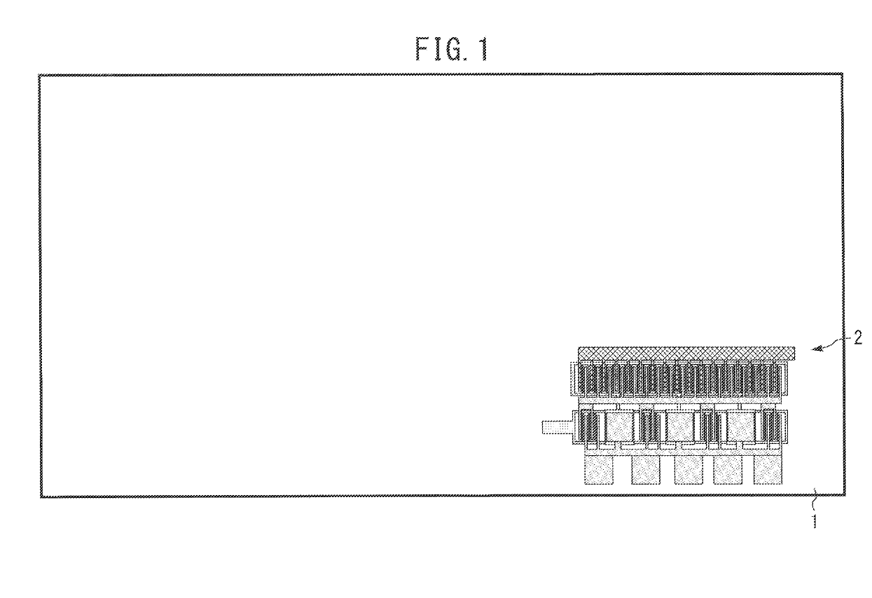

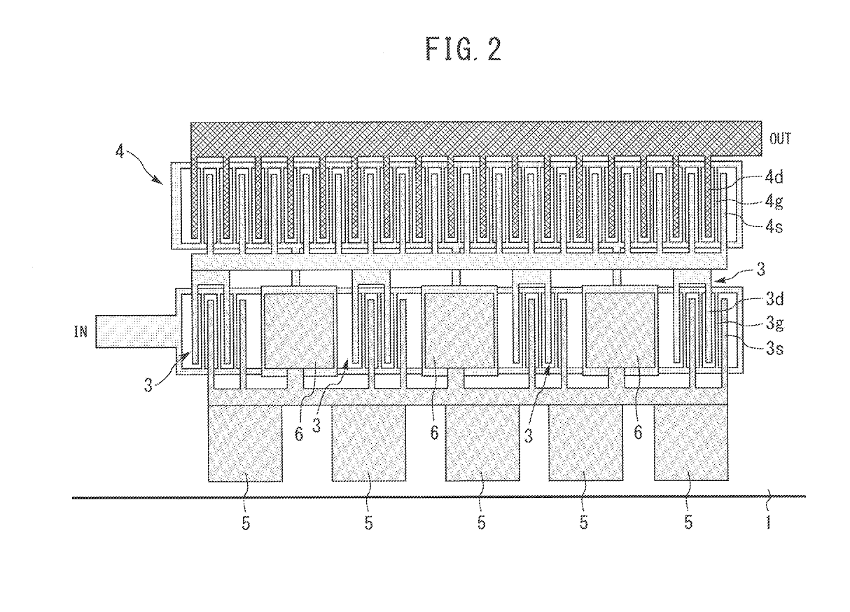

FIG. 1 is a top view illustrating a cascode amplifier according to Embodiment 1 of the present invention. FIG. 2 is a partially enlarged top view of FIG. 1. A cascode amplifier 2 is provided on part of a principal surface of a silicon substrate 1.

A plurality of source-grounded transistors 3 are connected in parallel with each other and a plurality of gate-grounded transistors 4 are connected in parallel with each other. The source-grounded transistor 3 has a gate 3g, a source 3s and a drain 3d, and the gate-grounded transistor 4 has a gate 4g, a source 4s and a drain 4d. The gate 3g of the source-grounded transistor 3 is an input terminal IN and the drain 4d of the gate-grounded transistor 4 is an output terminal OUT.

The sources 4s of the plurality of gate-grounded transistors 4 are connected to the drains 3d of the plurality of source-grounded transistors 3 respectively. That is, the gate-grounded transistors 4 and the source-grounded transistors 3 are cascode-connected. A plurality of ground pads 5 are connected to the sources 3s of the plurality of source-grounded transistors 3.

A plurality of grounding capacitances 6 are connected between the gates 4g of the plurality of gate-grounded transistors 4 and the ground pads 5. The plurality of source-grounded transistors 3 and the plurality of grounding capacitances 6 are alternately arranged between the ground pads 5 and the plurality of gate-grounded transistors 4.

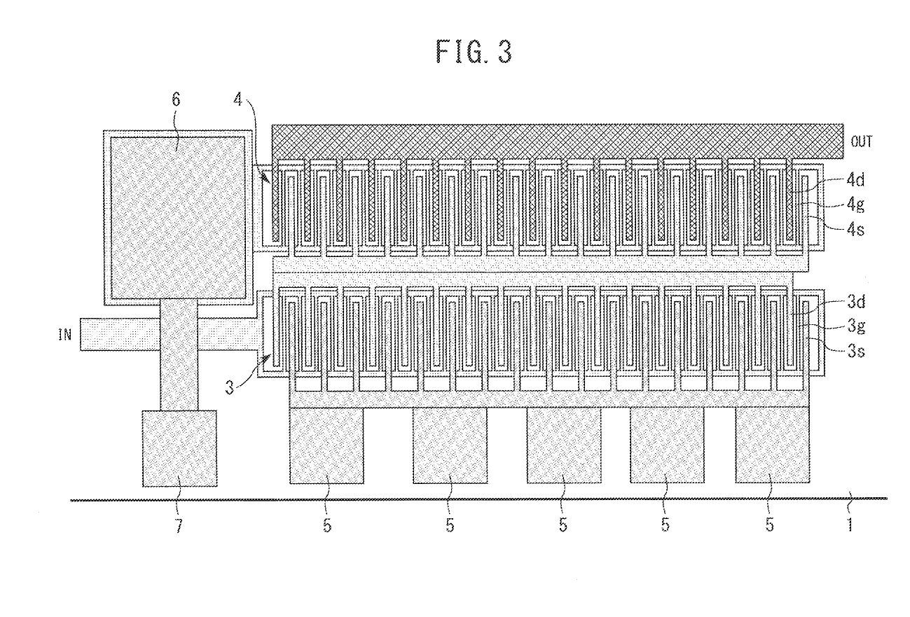

Next, effects of the present embodiment will be described in comparison with a comparative example. FIG. 3 is an enlarged top view illustrating a cascode amplifier according to a comparative example. In the comparative example, ground pads 5 connected to sources of source-grounded transistors 3 and a ground pad 7 connected to a grounding capacitance 6 are provided separately. As a result, the number of ground pads increases, causing an increase in the chip size. On the other hand, in the present embodiment, since the same ground pads are shared as ones connected to the grounding capacitances 6 and ones connected to the sources of the source-grounded transistor 3, it is possible to reduce the chip size.

Furthermore, in the present embodiment, the plurality of source-grounded transistors 3 and the plurality of grounding capacitances 6 are alternately arranged between the ground pads 5 and the plurality of gate-grounded transistors 4. This can reduce variations in the distance from the gate-grounded transistors 4 to the grounding capacitances 6, thus preventing unbalanced operation. Since the distance from the gates 4g of the gate-grounded transistors 4 to the grounding capacitances 6 become shorter, the wiring resistance is reduced, and high-frequency grounding of the gates 4g of the gate-grounded transistors 4 becomes sufficient, and it is thereby possible to improve the gain, output and efficiency of the cascode amplifier.

On the silicon substrate 1, the ground pads 5, the plurality of source-grounded transistors 3 and the plurality of gate-grounded transistors 4 are arranged in order from the edge of the silicon substrate 1 toward the inside. This can shorten the length of the wires connecting the ground pads 5 and external ground. It is also possible to reduce an inductance produced by wiring from the sources 3s of the source-grounded transistors 3 to the ground pads 5. As a result, a high gain can be obtained.

Note that the source-grounded transistors 3 and the gate-grounded transistors 4 may be NMOS-type transistors, PMOS-type transistors or SiGe-HBT or the like. The grounding capacitances 6 may be MIM (Metal-Insulation Metal) capacitances or MOS (Metal Oxide Semiconductor). There are no constraints on unit gate widths of the source-grounded transistors 3 and the gate-grounded transistors 4, and unit gate widths are set so as to allow the source-grounded transistors 3 and the grounding capacitances 6 to be alternately arranged.

### Embodiment 2

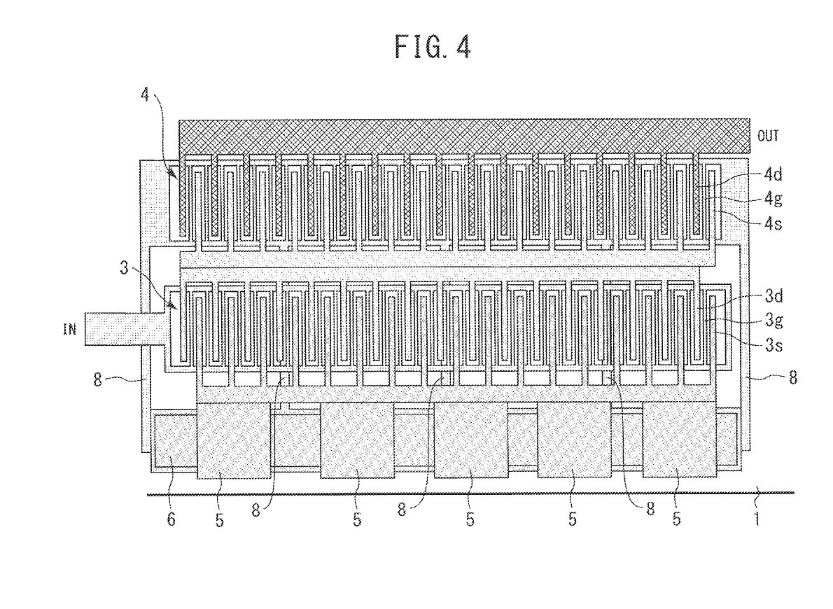

FIG. 4 is an enlarged top view illustrating a cascode amplifier according to Embodiment 2 of the present invention. As in the case of Embodiment 1, the same ground pads are shared as ones connected to a grounding capacitance 6 and ones connected to sources 3s of source-grounded transistors 3. Unlike Embodiment 1, the grounding capacitance 6 is arranged below ground pads 5. This can further reduce the chip size compared to Embodiment 1.

The grounding capacitance 6 is connected to gates 4g of a plurality of gate-grounded transistors 4 via a plurality of wires 8. This makes it possible to reduce variations in the distance from the gate-grounded transistors 4 to the grounding capacitance 6 and thereby prevent unbalanced operation. Since the distance from the gates 4g of the gate-grounded transistors 4 to the grounding capacitance 6 is shortened, the wiring resistance becomes smaller, and high-frequency grounding of the gates 4g of the gate-grounded transistors 4 becomes sufficient, and it is thereby possible to improve the gain, output and efficiency of the cascode amplifier.

The grounding capacitance 6 may be a MIM capacitance or MOS, but in the case of a MIM capacitance, its underlying electrode can also be shared with the gates 4g of the gate-grounded transistors 4 and its overlying electrode can also be shared with the ground pads 5.

### Embodiment 3

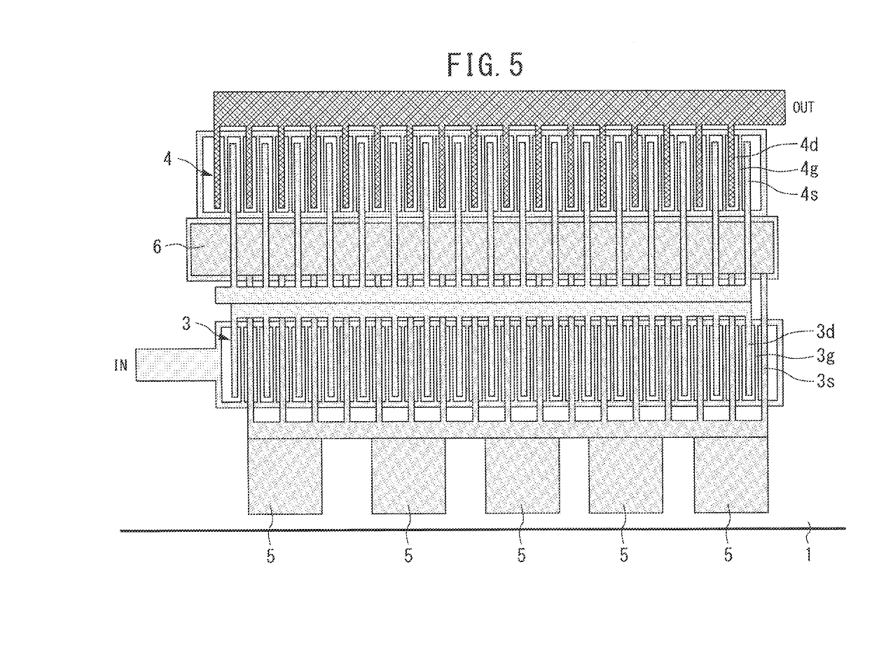

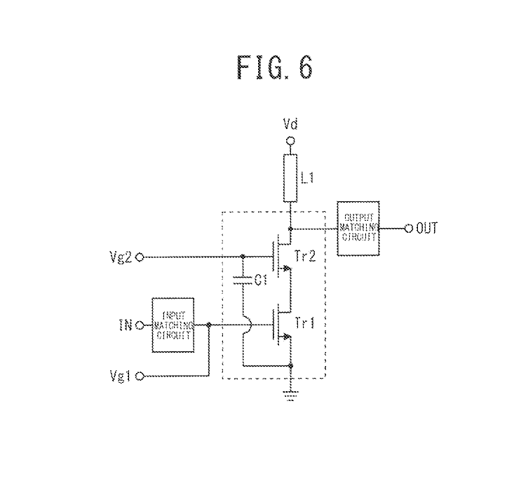

FIG. 5 is an enlarged top view illustrating a cascode amplifier according to Embodiment 3 of the present invention. Unlike Embodiment 1, a grounding capacitance 6 is arranged between a plurality of source-grounded transistors 3 and a plurality of gate-grounded transistors 4. This can reduce variations in the distance from the gate-grounded transistors 4 to the grounding capacitance 6, and thereby prevent unbalanced operation. Since the distance from gates 4g of the gate-grounded transistors 4 to the grounding capacitance 6 is shortened, wiring resistance becomes smaller, and high-frequency grounding of the gates 4g of the gate-grounded transistors 4 becomes sufficient, and it is thereby possible to improve the gain, output and efficiency of the cascode amplifier.

Furthermore, as in the case of Embodiment 1, since the same ground pads are used as ones connected to the grounding capacitance 6 and ones connected to the sources 3s of the source-grounded transistors 3, the chip size can be reduced.

The grounding capacitance 6 may be a MIM capacitance or MOS, but in the case of a MIM capacitance, its overlying electrode or underlying electrode can also be shared with the gates 4g of the gate-grounded transistors 4.

### DESCRIPTION OF SYMBOLS

1 silicon substrate (semiconductor substrate), 2 cascode amplifier, 3 source-grounded transistor, 4 gate-grounded transistor, 5 ground pad, 6 grounding capacitance

1. A cascode amplifier comprising:
a plurality of source-grounded transistors connected in parallel with each other;
a plurality of gate-grounded transistors connected in parallel with each other and having sources connected to drains of the plurality of source-grounded transistors respectively;
ground pads connected to sources of the plurality of source-grounded transistors; and
a plurality of grounding capacitances connected between gates of the plurality of gate-grounded transistors and the ground pads,
wherein the plurality of source-grounded transistors and the plurality of grounding capacitances are alternately arranged between the ground pads and the plurality of gate-grounded transistors.

2. A cascode amplifier comprising:
a plurality of source-grounded transistors connected in parallel with each other;
a plurality of gate-grounded transistors connected in parallel with each other and having sources connected to drains of the plurality of source-grounded transistors respectively;
ground pads connected to sources of the plurality of source-grounded transistors; and
a grounding capacitance connected between gates of the plurality of gate-grounded transistors and the ground pads,
wherein the grounding capacitance is arranged below the ground pads and connected to gates of the plurality of gate-grounded transistors via a plurality of wires.

3. A cascode amplifier comprising:
a plurality of source-grounded transistors connected in parallel with each other;
a plurality of gate-grounded transistors connected in parallel with each other and having sources connected to drains of the plurality of source-grounded transistors respectively;
ground pads connected to sources of the plurality of source-grounded transistors; and
a plurality of grounding capacitances respectively connected between gates of the plurality of gate-grounded transistors and the ground pads,
wherein the plurality of grounding capacitances are arranged between the plurality of source-grounded transistors and the plurality of gate-grounded transistors,
wire lengths between the plurality of grounding capacitances and the ground pads are equal to each other.

4. (canceled)
